(19) United States
(12) Patent Application Publication
(10) Pub. No.: US 2007/0224708 A1
(43) Pub. Date: Sep. 27, 2007

(54) Mass pulse sensor and process-gas system and method

(76) Inventors: Sowmya Krishnan, Newark, CA (US); Mohamed Saleem, Fremont, CA (US)

Correspondence Address: PERKINS COIE LLP, P.O. BOX 2168, MENLO PARK, CA, 94026, US

(21) Appl. No.: 11/386,292

(22) Filed: Mar. 21, 2006

(51) Int. Cl. H01L 21/00

(52) U.S. Cl. 438/5

(57) ABSTRACT

An improved valve device, a valved process-gas apparatus, and a method for confirming operations in a gas-process system are disclosed. The valve device includes an electronically controlled valve designed to cycle between closed and open conditions, with closed-to-open and open-to-closed response times less than about 250 ms, to control the flow of a gas through the valve. A sensor disposed at the downstream side of the valve is operable to (i) detect the presence of at least a threshold amount of gas during the period of the valve's closed-to-open response, and (ii) to detect the absence of at least a threshold amount of gas after the period of the valve's open-to-closed response, thus confirming successful operation of the valve.

### FIELD OF THE INVENTION

The present invention relates to a process-gas system and method having a mass-pulse sensor for controlling the supply of process gas in the system, and in particular, to a method and system for surface deposition requiring multiple and repeated substrate treatments with one or more process gases.

### BACKGROUND OF THE INVENTION

Advanced microelectronic devices are being manufactured with ever increasing device density and complexity. The device dimensions are decreasing in both the lateral and vertical directions. Smaller device elements allow for increasingly complex, faster, and more powerful devices.

A variety of microelectronic devices are made using advanced deposition techniques, such as atomic layer deposition (ALD), sequential layer deposition, cyclic layer deposition, and nano layer deposition (NLD), and the like, in which a substrate is successively and repeatedly treated with one or more process gases. The “time scale” of the reaction in these deposition techniques is ideally on the order of less than 1 second per cycle, that is, less than 1 sec per layer deposited. Traditional gas delivery, control, and measurement technologies that exhibit response times of approximately 1 second are generally unsuitable for these technologies.

To this end, valves capable of fast response times as low as 5 to 20 msec have been developed. When placed in-line in a process-gas supply assembly, and under the control of a suitable microprocessor, such rapid-response valves are capable of cycling rapidly between open and closed conditions, and thus capable of delivering a gas at a precise time and over a precise duration to the substrate being processed, during each processing cycle. Such rapid-response valves have significantly reduced gas-processing cycle times, down to a second or less. However, because the quality and performance of the device being produced is sensitive to both the timing and amount of processing gas delivered during each processing cycle, including both “on” and “off” phases of each cycle, any defects in the operation of the valve can lead to accumulating errors in the device being manufactured. Unfortunately, these errors may not be detected until the performance characteristics of a batch of manufactured devices is checked for quality.

It would therefore be desirable to provide, in a manufacturing setting in which one or more process gases are delivered alternately and repeatedly to a substrate, under the control of one or more rapid-response valves, apparatus for monitoring the operation of the valve during the manufacturing process, to ensure that at each processing cycle, process gas is delivered to the substrate over a precisely determined time, and only when needed.

### SUMMARY OF THE INVENTION

The invention includes, in one embodiment, an improvement in electronically controlled valve device having a valve designed to cycle between closed and open conditions, with closed-to-open and open-to-closed response times less than about 250 ms, to control the flow of a gas through the valve in a downstream direction, from an upstream flow chamber to a downstream station. The improvement includes a sensor disposed at the downstream side of the valve, operable to (i) detect the presence of at least a threshold amount of gas during the period of the valve's closed-to-open response, and (ii) to detect the absence of at least a threshold amount of gas after the period of the valve's open-to-closed response, wherein the desired operation of the valve to deliver gas to the station within a selected time after opening the valve, and to prevent flow of gas to the gas after the valve is closed, over a plurality of valve cycles, can be confirmed. The improved valve is also referred to herein a mass-pulse sensor (MPS).

In various embodiments, the sensor in the MPS is operable to detect the presence of gas during the first 20% of the period of the valve's closed-to-open response. For example, where the valve has a closed-to-open response time of less than about 100 msec, the sensor may be operable to detect the presence of gas during the first 10-20 msec of the period of the valve's closed-to-open response. The sensor may further be operable to detect the absence of gas immediately after the period of the valve's open-to-closed response.

The gas-amount threshold applied during sensor operation (i) may be the same as that applied during sensor operation (ii), or the gas-amount threshold applied during sensor operation (i) may be substantially higher than the threshold applied during sensor operation (ii).

In another aspect, the invention includes a gas-delivery apparatus for delivering a process gas to a substrate in a station. The system includes a defined-volume flow chamber extending between upstream and downstream ends, and a gas-supply assembly communicating with the upstream end of the chamber, for supplying such process gas thereto at a controlled rate, to fill the chamber with a given amount of process gas. An electronically controlled valve in the system is designed to cycle between closed and open conditions, with closed-to-open and open-to-closed response times less than about 250 ms, to control the flow of a gas from the downstream end of the flow chamber to such station. A sensor disposed at the downstream side of the valve is operable to (i) detect the presence of at least a threshold amount of gas during the period of the valve's closed-to-open response, and (ii) to detect the absence of at least a threshold amount of gas after the period of the valve's open-to-closed response time. A controller in the system is operatively connected to said valve and sensor for (i) controlling the cycling of the valve between its closed and open conditions, and (ii) confirming, from signals received from the sensor, the desired operation of the valve to deliver gas to such station within a selected time after opening the valve, and to prevent flow of gas to the gas after the valve is closed, over a plurality of valve cycles.

The gas supply assembly may include a pressure regulator adapted to receive process gas from a process-gas source, to regulate the flow rate of gas from such source, a pressure transducer downstream of said regulator, for measuring the output pressure from said pressure regulator, and a fixed orifice flow restrictor downstream of said transducer, for limiting the flow of gas from the regulator to said chamber, where the assembly is designed to fill the chamber with a given amount of process gas during the period when said valve is closed.

The sensor may be, for example, a thermal sensor, a pressure sensor, an optical sensor, an acoustic sensor, a quartz balance sensor, a chemical sensor, or combinations thereof. The valve may be, for example, a pneumatic valve, an electromagnetic valve, a solenoid valve, or a piezoelectric valve.

In still another aspect, the invention provides an improvement in a method for processing a substrate, by alternating and repeatedly exposing the substrate to a process gas, by the steps of (i) filling a gas flow chamber with the process gas, (ii) cycling a valve between closed and open conditions, with closed-to-open and open-to-closed response times less than about 250 ms, to alternately and repeatedly release gas from said flow chamber to said station, under the control of an electronic controller, an improvement for confirming that each of desired gas-exposing steps has occurred. The improvement includes sensing, downstream of the valve, (i) the presence of at least a threshold amount of gas during the period of the valve's closed-to-open response, and (ii) the absence of at least a threshold amount of gas after the period of the valve's open-to-closed response time.

These and other objects and features of the invention will become more fully apparent when the following detailed description of the invention is read in conjunction with the accompanying drawings.

### BRIEF DESCRIPTION OF THE DRAWINGS

FIG. 1 is a schematic block diagram of the operational components of mass-pulse sensor constructed in accordance with the invention;

FIG. 2 shows typical valve and sensor profiles in the operation of an MPC of the invention over a number of process cycles;

FIG. 3 shows gas-supply and control components in a gas-process system constructing in accordance with an embodiment of the invention; and

FIG. 4 shows a system having a pair of coordinated gas-supply and control components, such as shown in FIG. 3.

### DETAILED DESCRIPTION OF THE INVENTION

The stringent requirements of the most advanced devices as well as projected future device devices have led to the development of advanced deposition techniques such as atomic layer deposition (ALD), sequential layer deposition, cyclic layer deposition, nano layer deposition (NLD), and the like. The “time scale” of the reactions used in these advanced deposition techniques is generally on the order of less than 1 second for each step. Traditional gas delivery, control, and measurement technologies that exhibit response times of approximately 1 second are not suitable for these technologies.

In the ALD process method, a substrate is exposed to a first precursor. Ideally, the precursor saturates the surface and forms a single monolayer on substrate. Excess amounts of the precursor do not react and are carried away through the system exhaust system. The process chamber is purged to remove the unreacted precursor and a second reactive gas is introduced. The second reactive gas reacts with the monolayer of the first precursor to deposit a single layer the target material. Again, the process chamber is purged to remove unreacted portions of the reactant gas as well as reaction by-products. This sequence is repeated until the final thickness of the target material is reached. On the molecular level, each of these steps is complete in a few milliseconds. Practically, each step takes a few seconds due to the hardware limitations of the gas delivery devices as cited earlier.

One important determination that should be made during each sequence is “Was gas delivered to substrate when the valve was switched on?” This is more important than determining “How much gas flowed?” As mentioned previously, small amounts of excess gas are simply removed from the process chamber during the purge step and do not contribute to the deposition of the material. The importance of this determination can be realized in the following example. An ALD process can be envisioned that deposits a single layer of SiO₂ during each full sequence as described above. Each SiO₂ layer will be approximately 2 Å (angstroms) in thickness. The target gate oxide thickness of advanced semiconductor devices is approximately 12 Å. Therefore, if a problem occurs and a gas does not flow during one of the steps, the resulting film will be only 10 Å in thickness, a decrease of almost 17%. This non-uniformity and lack of control is unacceptable in the manufacture of advanced semiconductor devices. This problem is currently addressed by making each of the steps cited above several seconds in length. This allows the current hardware used in the delivery of gases to measure and verify the flow. However, it increases the time required for the deposition, wastes valuable precursor and reactive gases, lowers the throughput of the method, increases the cost of ownership for the device manufacture as well as other problems. Moreover, as will be seen below, the process system may be designed to include, upstream of the valve, a gas reservoir or chamber that fills under by a pressurized gas-flow assembly that ensures that the reservoir will be refilled with a desired amount of gas following each valve-open/close cycle.

A second important question, for purposes of ensuring the quality of the process steps, is: “Did process gas stop flowing when the valve was switched off?” If, for example, the valve seal is contaminated, e.g., by gas-borne particles, the valve may continue to leak gas after it is switched off. Leaking process gas may interfere with the subsequent process step(s) carried out on the substrate surface and/or may defeat the ability of subsequently applied purge gas to completely remove unbound process gas from the substrate.

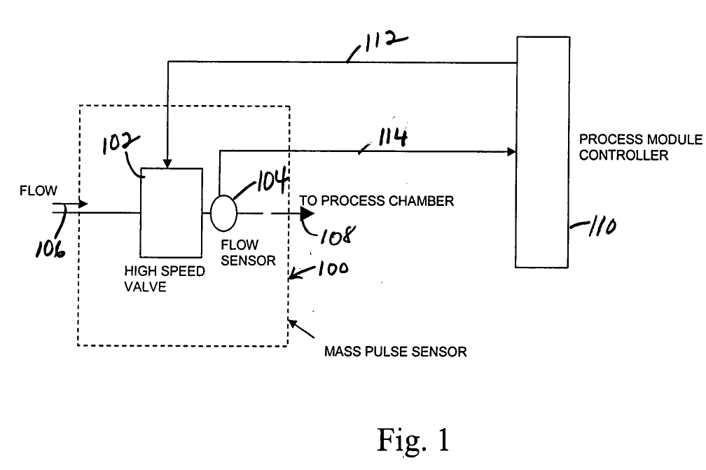

The present invention employs a gas-sampling sensor placed downstream of the valve to (i) detect the presence of at least a threshold amount of gas during the period of the valve's closed-to-open response, and (ii) to detect the absence of at least a threshold amount of gas after the period of the valve's open-to-closed response. For the convenience of this teaching, the combination rapid-response valve and mass sensor are referred to collectively as a “mass pulse sensor” or “MPS”. This MPS is designated at 100 in FIG. 1, which illustrates operational components of a gas process system that are involved in valved gas flow. As seen in the figures, MPS 100 includes a high-speed valve or valve device 102, and a gas sensor 104 disposed immediately downstream of the valve for measuring threshold amounts of gas flowing through the valve in an upstream-to-downstream direction from a flow chamber (not shown) indicated by arrow 106 to a process chamber or station (not shown), indicated by arrow 108.

Valve switching is controlled by a process controller 110 operatively connected to valve through a line 112. The controller receives information from sensor 104 through a line 114. The controller operates to switch the valve from its closed to its open condition at pre-set intervals, e.g., once every second, to allow a charge of process gas to move or be drawn (the process station is typical under a vacuum) from the gas flow reservoir, which contains a full charge or process gas, through the valve onto the substrate or workpiece in the process station. After a selected gas-discharge time, typically 50-250 ms, the controller will switch the valve from its open-to-closed condition, blocking the flow of gas through the valve and allowing the gas-flow reservoir to refill with a charge of process gas.

Valve 102 MPS receives power from the system through the power module forming part of controller 110. The power connections typically consist of 0V, +15 VDC, and −15 VDC. The MPS may receive either analog or digital pulse commands, preferably digital pulse commands. The pulse commands drive valve 102 to open at a selected time for a prescribed amount of time, at which point the valve closes, e.g., under the action of a biasing spring.

In the case of a gas line conveying a reactive process gas, the valve is a positive shutoff, normally closed (NC) valve, meaning that gas only flows when the valve is activated. The rapid-response valve may be a pneumatic valve, a solenoid vale, an electromagnetic valve, a piezoelectric valve, or the like, all of which are commercially available. Preferably the valve is a pneumatic valve capable of pulse times of less than 250 ms, preferably less than 100 ms, and most preferably less than 50 ms. By response time is meant the time required to completely open the valve from the time when it is first switch on or open. During this response time, progressively more gas flow through the valve until it reaches its fully open condition at the end of the response time. Commercially available pneumatic valves such as supplied by Swagelok (Solon, Ohio) have a response time of 20 ms from fully closed to fully open. Electromagnetic and piezoelectric valves may have issues with heat dissipation during the rapid cycling and this may lead to shorter valve lifetimes. Pneumatic valves will yield reliable performance over more than 25 million cycles.

In the case of a gas line conveying purge gases, the valve will be a positive shutoff, normally open (NO) valve, meaning that gas flows continuously until the valve is activated. Such normally open, rapid-response valves having performance characteristics, e.g., response times, similar to above-described normally closed valves are also commercially available.

The operation of sensor 104, and the information it supplies to the processor, will now be considered. Since the goal is to determine only “if” mass flowed rather than the exact “amount” of gas that flowed, any number of sensor technologies would be suitable for incorporation into the MPS. Examples of sensor types suitable for the invention include micro-machined sensors, pressure sensors, optical sensors, acoustic sensors, quartz balance sensors, chemical sensors, and the like. More generally, the purpose of the sensor is to measure some threshold amount of gas, and this threshold can be quite low, e.g., corresponding to a very low-level gas leak through the valve. Thus, the sensor may be designed simply to detect the presence or absence of a threshold amount of gas in its sensing station. Alternatively, the sensor may have the capability of measuring different threshold levels of gas at different times in its operation. Thus, for example, when the sensor is used to detect the presence of gas flow through the valve in its opened condition, the sensor threshold may be set to determine if an amount of gas corresponding to a fully charged flow chamber is detected, whereas for detecting gas follow in the valve closed condition, the sensor may be set to detect a much lower threshold of gas corresponding to a slow leak through the valve. A preferred sensor is a micromachined sensor, such as a Merit 3000 Series sensor supplied by Merit Sensor Systems (Santa Clara, Calif.) or a SM Series sensor supplied by Silicon Microstructures Inc. (Milpitas, Calif.).

The sensor may operate to make continuous gas measurements throughout the entire valve cycle, allowing the controller to sample gas flow through the valve continuously. However, it is only required that the sensor make gas measurements at two points during valve operation. The first measurement, for detecting a “gas-on” condition, occurs shortly after the valve is activated from its closed-to-open condition, preferably during the closed-to-open response time of the valve, and typically during the first 20-40% of the valve's closed-to-open response time, e.g., during the first 10% of the response time. Thus, for a valve having a closed-to-open response time of 100 msec, the “gas-on” measurement would be taken within the first 20-40 msec after the valve is switched on, e.g., at the point 10 msec into the response time. As just noted, the important information at this point is that gas in the sensor is above a given threshold, which may be a quite low threshold, simply to confirm that the valve has opened.

The second measurement, for determining a “gas-off” condition, is taken after the valve has been switched off, and preferably immediately after the valve's open-to-closed response time. Thus, if the response time for valve closure is 50 msec, the presence of a threshold amount of gas could be monitored during time 50-100 msec after the initiation of valve closure. As above, the gas threshold monitored at this stage may be the same low threshold monitored at valve opening, or may be substantially less then the “gas-on” threshold. The “gas-off” measurement is designed to detect the presence of any process gas after valve closure, indicating that is valve has closed completely.

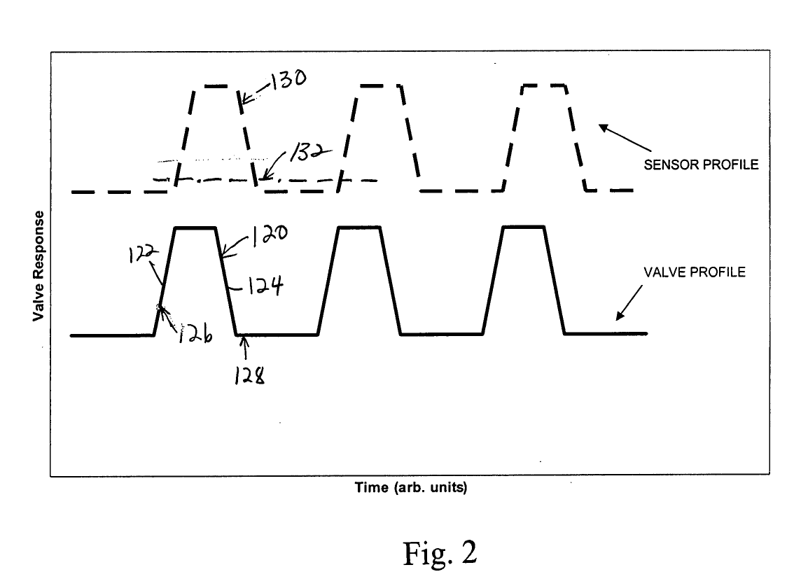

FIG. 2 shows valve and sensor profiles in a typical operation of the MPS during a process of the invention. The lower, solid-line profile shows a series of pulses, such as pulse 120, with the leading side of the peak, such as at 122, representing closed-to-open response time, and the trailing side of each peak, such as at 124, representing the open-to-closed response times. As noted above, the gas-on sensor measurements is performed during the closed-to-open response time in each peak, such as indicated by arrow 126, and the second, “gas-off” measurement is performed shortly after the open-to-closed response time at the completion of each pulse, such as indicated by arrow 128.

The upper, dashed curve represent an idealized gas-flow measurement generated by making continuous gas readings at the sensor, and contains peaks, such as peak 130, corresponding to the valve-response peaks. The two plots are substantially overlapping, but offset by a small time increment representing the delay in gas flow through the valve as the valve is opened or closed. A dash-dot line 132 in the upper plot represents a threshold level of gas detected by the sensor at the “gas-on” and “gas-off” measurements. As indicated, this threshold can be quite low relative to the actual amount of gas flowing through the valve, but sufficient to detect that the valve has been switched on. The low threshold is effective to detect low amounts of gas leakage following valve closure. Although the MPS has been described with respect to a normally closed valve, it will be appreciated that the sensor would operate to make the same gas-on and gas-off measurement when used in combination with a normally open valve. That is, the two important gas-threshold measurements are (i) the beginning of gas flow when the valve is opened, and (ii) the end of gas flow when the valve is closed.

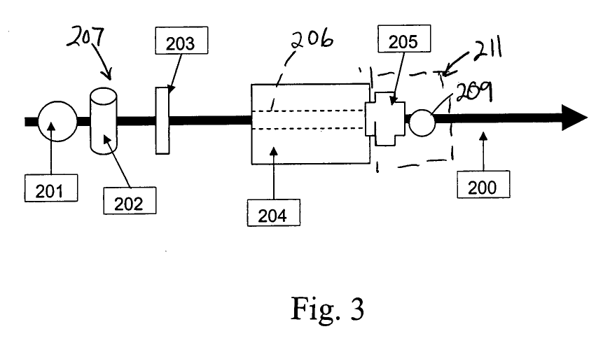

Referring now to FIG. 3, the use of the MPS can be described in a typical gas delivery system. The general piping of the gas delivery line is illustrated by arrow, 200. Other elements such as purge lines, valves, etc. that are not critical to the present invention are omitted included for clarity. The gas supply may be from a high pressure cylinder and is set to a more reasonable level by pressure regulator 201. A gas-supply assembly in the system, indicated generally at 207, includes a stable pressure regulator 201 that is set during the installation of the system, a pressure transducer 202 capable of measuring the output pressure from pressure regulator 201, and a fixed-orifice flow restrictor 203 for limiting the flow rate of gas into a gas-flow chamber or reservoir 206. Although not shown here, output from the pressure transducer may be supplied to the controller, so that the status of gas supply to the valve can be confirmed. The components of the gas flow assembly are designed and set to fully recharge chamber 207 after each valve-controlled gas release. That is, the flow of gas into the chamber from the gas-flow assembly is such as to fully refill the chamber during the “off” period of the valve. This ensures, when the valve is opened, that a known amount of process gas is released into the process station. Because the components of the gas-flow assembly do not involve high-speed mechanical movement, and are stable and reliable, it is not necessary to confirm that the chamber has been fully refilled during a process cycle, or that a given amount of gas is released upon valve opening. It is only important to detect that gas is flowing through the valve at some threshold level, confirming that the valve has opened.

The input pressure to MPS, that is, the pressure within the charged chamber, is typically in a range from about 500 Torr to 2000 Torr; and the outlet pressure from the pulsed valve is typically between 0.1 and 1000 mTorr. During each closed portion of the valve cycle, the volume of gas contained in the chamber, which has a typical volume between about 1-15 cc, will be recharged. That is, after the valve closes, process gas is quickly replenished and is ready for the beginning of the next pulse. Since the temperature, pressure, pulse time, and gas constants are known, the total mass of the gas that is delivered through pulsed valve during each pulse can be accurately calculated. Alternatively, the total mass of the gas that is delivered through pulsed valve during each pulse can be accurately measured empirically during the calibration of the gas line during manufacturing if desired.

In the system shown in FIG. 3, the rapid-response valve is indicated at 205 and the sensor, at 209. The discussed above, the valve and sensor form a mass pulse sensor (MPS) 211 forming one aspect of the invention. In one embodiment of the invention the rapid-response valve and sensor are integrated into a unitary MPS device. In another embodiment, all of the components of the gas-flow assembly and the MPS are designed, manufactured, and delivered as an integrated, single part. In this way, the variables such as gas line size, distances between the components, orifice sizes, internal volume, and the like can be fixed and an integrated component with a known, well characterized performance can be delivered and designed into the semiconductor equipment supplier's gas box. Values of orifice size, pressure settings, internal volume, and pulse length can be optimized across a suitable range of mass flows and the semiconductor equipment supplier would be able to select a standardized product that fulfills its needs. This will have the benefits of lower manufacturing costs, smaller spares inventory, better reproducibility, greater design flexibility, improved consistency, lower gas usage, lower gas cost, as well as others.

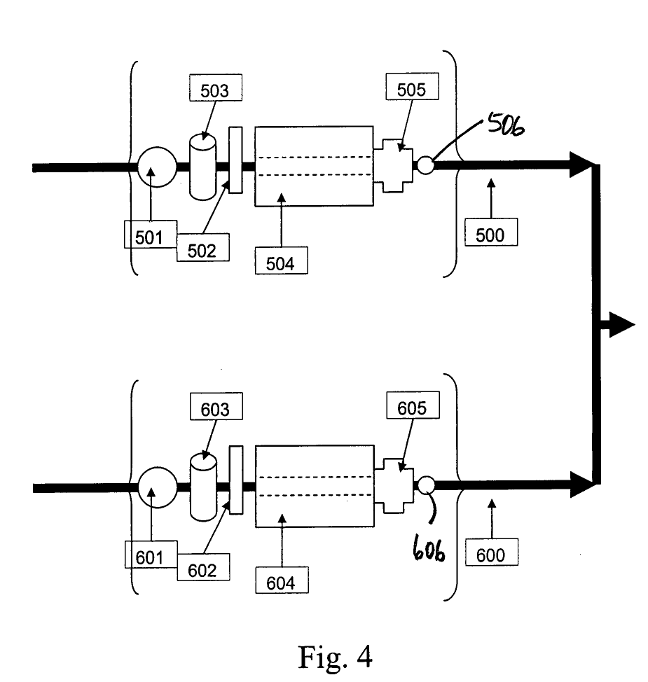

FIG. 4 illustrates the use a synchronized pair of the integrated process-gas systems such as described with respect to FIG. 3. The first system is includes a regulator 501, a pressure transducer 503, a fixed orifice constrictor 502, a flow chamber 504, a positive shut-off, normally open valve 505, and a sensor 506. In this case, valve 505 is a normally open valve and the purge gas flows continuously through a conduit 500 until the valve is commanded to close. The operation of sensor 506 to monitor the condition of valve 505 is as described above.

The second process-gas system includes a regulator 601, a pressure transducer 603, a fixed orifice constrictor 602, a flow chamber 604, a positive shut-off, normally closed valve 605, and a sensor 606. This system is used to supply a precursor or reactive gas to the process chamber through a conduit, 600. In this case, valve 605 is a normally closed valve and the gas is allowed to flow only when the valve is commanded to open. The two systems may be synchronized so that only one of the channels is active at one time. This insures that the proper process method is practiced during the deposition sequence.

The foregoing descriptions of specific embodiments of the present invention have been presented for the purpose of illustration and description. They are not intended to be exhaustive or to limit the invention to the precise forms disclosed, and obviously many modifications, embodiments, and variations are possible in lights of the above teaching. It is intended that the scope of the invention be defined by the Claims appended hereto and their equivalents.

What is claimed is:

1. In an electronically controlled valve device having a valve designed to cycle between closed and open conditions, with closed-to-open and open-to-closed response times less than about 250 ms, to control the flow of a gas through the valve in a downstream direction, from an upstream flow chamber to a downstream station, an improvement comprising
a sensor disposed at the downstream side of the valve, operable to (i) detect the presence of at least a threshold amount of gas during the period of the valve's closed-to-open response, and (ii) to detect the absence of at least a threshold amount of gas after the period of the valve's open-to-closed response,
wherein the desired operation of the valve to deliver gas to such station within a selected time after opening the valve, and to prevent flow of gas to the gas after the valve is closed, over a plurality of valve cycles, can be confirmed.

2. The improvement of claim 1, wherein the sensor is operable to detect the presence of gas during the first 20% of the period of the valve's closed-to-open response.

3. The improvement of claim 2, wherein the valve has a response time of less than about 100 msec, and the sensor is operable to detect the presence of gas during the first 20 msec of the period of the valve's closed-to-open response.

4. The improvement of claim 1, wherein the sensor is operable to detect the absence of gas immediately after the period of the valve's open-to-closed response.

5. The improvement of claim 1, wherein the gas-amount threshold applied during sensor operation (i) is the same as that applied during sensor operation (ii).

6. The improvement of claim 1, wherein the gas-amount threshold applied during sensor operation (i) is substantially higher than the threshold applied during sensor operation (ii).

7. A gas-delivery apparatus for delivering a process gas to a substrate in a station, comprising:
a defined-volume flow chamber extending between upstream and downstream ends,
a gas-supply assembly communicating with the upstream end of the chamber, for supplying such process gas thereto at a controlled rate, to fill the chamber with a given amount of process gas,
an electronically controlled valve designed to cycle between closed and open conditions, with closed-to-open and open-to-closed response times less than about 250 ms, to control the flow of a gas from the downstream end of the flow chamber to such station,
a sensor disposed at the downstream side of the valve, operable to (i) detect the presence of at least a threshold amount of gas during the period of the valve's closed-to-open response, and (ii) to detect the absence of at least a threshold amount of gas after the period of the valve's open-to-closed response time, and
a controller operatively connected to said valve and sensor for (i) controlling the cycling of the valve between its closed and open conditions, and (ii) confirming, from signals received from the sensor, the desired operation of the valve to deliver gas to such station within a selected time after opening the valve, and to prevent flow of gas to the chamber after the valve is closed, over a plurality of valve cycles.

8. The apparatus of claim 7, wherein said gas-supply assembly includes a pressure regulator adapted to receive process gas from a process-gas source, to regulate the flow rate of gas from such source, a pressure transducer downstream of said regulator, for measuring the output pressure from said pressure regulator, and a fixed-orifice flow restrictor downstream of said transducer, for limiting the flow of gas from the regulator to said chamber, and the assembly is designed to fill the chamber with a given amount of process gas during the period when said valve is closed.

9. The apparatus of claim 7, wherein the sensor is operable to detect the presence of gas during the first 20% of the period of the valve's closed-to-open response.

10. The apparatus of claim 9, wherein the valve has a response time of less than about 100 msec, and the sensor is operable to detect the presence of gas during the first 20 msec of the period of the valve's closed-to-open response.

11. The apparatus of claim 7, wherein the sensor is operable to detect the absence of gas immediately after the period of the valve's open-to-closed response.

12. The apparatus of claim 7, wherein the gas-amount threshold applied during sensor operation (i) is the same as that applied during sensor operation (ii).

13. The apparatus of claim 7, wherein the gas-amount threshold applied during sensor operation (i) is substantially higher than the threshold applied during sensor operation (ii).

14. The apparatus of claim 7, wherein said sensor is selected from the group consisting of a thermal sensor, a pressure sensor, an optical sensor, an acoustic sensor, a quartz balance sensor, a chemical sensor, and combinations thereof.

15. The apparatus of claim 7, wherein said shutoff valve is selected from the group consisting of a pneumatic valve, an electromagnetic valve, a solenoid valve, or a piezoelectric valve.

16. In a method for processing a substrate, by alternating and repeatedly exposing the substrate to a process gas, by the steps of (i) filling a gas flow chamber with the process gas, (ii) cycling a valve between closed and open conditions, with closed-to-open and open-to-closed response times less than about 250 ms, to alternately and repeatedly release gas from said flow chamber to said station, under the control of an electronic controller, an improvement for confirming that each of desired gas-exposing steps has occurred, comprising the steps of
sensing, downstream of the valve (i) the presence of at least a threshold amount of gas during the period of the valve's closed-to-open response, and (ii) the absence of at least a threshold amount of gas after the period of the valve's open-to-closed response time.
